(19) United States
(12) Patent Application Publication
(10) Pub. No.: US 2007/0190794 A1
(43) Pub. Date: Aug. 16, 2007

(54) Conductive polymers for the electroplating

(75) Inventors: Jonathan Gorrell, Gainesville, FL (US); Mark Davidson, Florahome, FL (US)

Correspondence Address: DAVIDSON BERQUIST JACKSON & GOWDEY LLP, 4300 WILSON BLVD., 7TH FLOOR, ARLINGTON, VA, 22203, US

(73) Assignee: Virgin Islands Microsystems, Inc.

(21) Appl. No.: 11/350,812

(22) Filed: Feb. 10, 2006

(51) Int. Cl. B05D 1/32; H01L 21/302; H01L 21/461

(52) U.S. Cl. 438/720; 438/708; 438/725

(57) ABSTRACT

A process to produce ultra-small structures of between ones of nanometers to hundreds of micrometers in size, in which the structures are compact, nonporous and exhibit smooth vertical surfaces. Such processing is accomplished using a non-conductive or semi-conductive substrate on which a layer of a conductive material, such as a conductive polymer, is applied, and on which a second layer of a masking material, such as a pattern resist material, is applied. Following patterning of the second resist layer, and either the full or partial etching of the conductive polymer, or alternatively omitting the step of etching the conductive layer, electroplating techniques will be used to produce ultra-small structures on the substrate or alternatively directly on the conductive layer, after which either all of remaining portions of the conductive polymer layer and the resist layer will be removed, or only the resist layer will be removed, or alternatively neither will be removed.

### RELATED APPLICATIONS

This application is related to U.S. patent applications Ser. No. 11/243,476 (the '476 application), filed on Oct. 5, 2005, and entitled “Structures and Methods For Coupling Energy From An Electromagnetic Wave,” Ser. No. 11/243,477 (the '477 application), filed on Oct. 5, 2005, and entitled “Electron Beam Induced Resonance,” Ser. No. 11/203,407 (the '407 application), filed on Aug. 15, 2005, and entitled “Method of Patterning Ultra-Small Structures,” and Ser. No. 10/917,511 (the '511 application), filed on Aug. 13, 2004, and entitled “Patterning Thin Metal Films by Dry Reactive Ion Etching.” Each of these applications is commonly owned at the time of filing this application, and the entire contents of each are fully incorporated herein by reference.

### COPYRIGHT NOTICE

A portion of the disclosure of this patent document contains material which is subject to copyright or mask work protection. The copyright or mask work owner has no objection to the facsimile reproduction by anyone of the patent document or the patent disclosure, as it appears in the Patent and Trademark Office patent file or records, but otherwise reserves all copyright or mask work rights whatsoever.

### FIELD OF THE DISCLOSURE

This disclosure relates to producing ultra-small metal structures using a combination of various coating, etching and electroplating processing techniques using a conductive polymer preferably on a non-conductive or semi-conductive substrate.

### INTRODUCTION AND SUMMARY

In its broadest form, the process disclosed herein produces ultra-small structures with a range of sizes described as micro- or nano-sized. The processing begins with a non-conductive substrates (e.g., glass, oxidized silicon, plastics and many others) or a semi-conductive substrate (e.g., doped silicon, compound semiconductor materials (GaAs, InP, GaN, . . . )) on which a layer of a conductive polymer (CP) is applied or coated. Alternatively, a hard substrate such as metal plates or sheets (e.g., aluminum, copper, iron alloys), ceramic materials can be used. A second mask layer is formed on that conductive polymer layer, the second layer comprising a layer of a non-conductive polymer or a photoresist (PR) material. The second layer is then patterned using one or more conventional processes, such as an exposure process, in which subsequent developing will remove selected unwanted portions of the second mask layer thereby exposing portions of the underlying conductive polymer layer. Then, the now exposed portions of the first conductive polymer layer can be etched away where there is no material of the second layer acting as a mask or a protective layer. This etching of the CP layer is preferably accomplished by use of chemical etching or Reactive Ion Etching (RIE) techniques, as are described in the above mentioned '407 application, to develop a final pattern in the CP layer. Alternatively, it is also with the scope of this invention to etch only portions of the full depth of the conductive polymer layer or to also develop the ultra small structure directly on the conductive polymer layer itself.

Following the foregoing steps that can include the patterning of one or both the CP and PR layers, portions thereof, or even where the conductive layer has not be etched. The now patterned base structure will be positioned in an electroplating bath and a desired metal will be deposited into the holes formed in either or both the first and second layers and on the layers exposed by one or more of the prior etching processing steps. Thereafter, the PR and CP layers can be removed leaving formed metal structures on the non-conductive substrate exhibiting an ultra small size, or alternatively the PR layer will be removed leaving the formed metal structures lying directly on the conductive polymer layer. Alternatively, the PR or CP or both layers can be left in place if they do not interfere with the ultimate function of the ultra small structures.

Electroplating is well known and is fully described in the above referenced '407 application.

Ultra-small structures encompass a range of structure sizes sometimes described as micro- or nano-sized. Objects with dimensions measured in ones, tens or hundreds of microns are described as micro-sized. Objects with dimensions measured in ones, tens or hundreds of nanometers or less are commonly designated nano-sized. Ultra-small hereinafter refers to structures and features ranging in size from hundreds of microns in size to ones of nanometers in size.

Ultra-small three-dimensional surface structures can be formed in which the structures are compact, nonporous and exhibit smooth vertical surfaces. Examples of the desired ultra-small structures, and their uses, are set forth in the '476 application and the '477 application.

The ability to build three-dimensional structures with smooth dense sidewalls employing the similar processing offers advantages to device designers. For example, smooth dense sidewalls increase the efficiency of optical device function. It may also be beneficial in some micro-fluidic applications.

### BRIEF DESCRIPTION OF FIGURES

The invention is better understood by reading the following detailed description with reference to the accompanying drawings in which:

FIG. 1 is a schematic diagram of the first step in the process of the present invention;

FIG. 2 is a schematic diagram of the second step in the process of the present invention;

FIG. 3 is a schematic diagram of the third step in the process of the present invention;

FIG. 4 is a schematic diagram of the fourth step in the process of the present invention;

FIG. 5 is a schematic diagram of the fifth step in the process of the present invention;

FIG. 6 is a schematic diagram of the final step in the process of the present invention which also shows an alternative step;

FIG. 7 is a schematic diagram of an alternative process according to the present invention;

FIG. 8 is a schematic diagram of the next step in an alternative process according to the present invention;

FIG. 9 is a schematic diagram of the next step in an alternative process according to the present invention;

FIG. 10 is a schematic diagram of a n exemplary final next step in an alternative process according to the present invention;

FIG. 11 is a diagrammatic diagram of an electroplating arrangement according to the present invention; and

FIGS. 12(a)-12(b) are plots of typical voltage waveform according to embodiments of the present invention.

### DESCRIPTION OF PRESENTLY PREFERRED EMBODIMENTS OF THE INVENTION

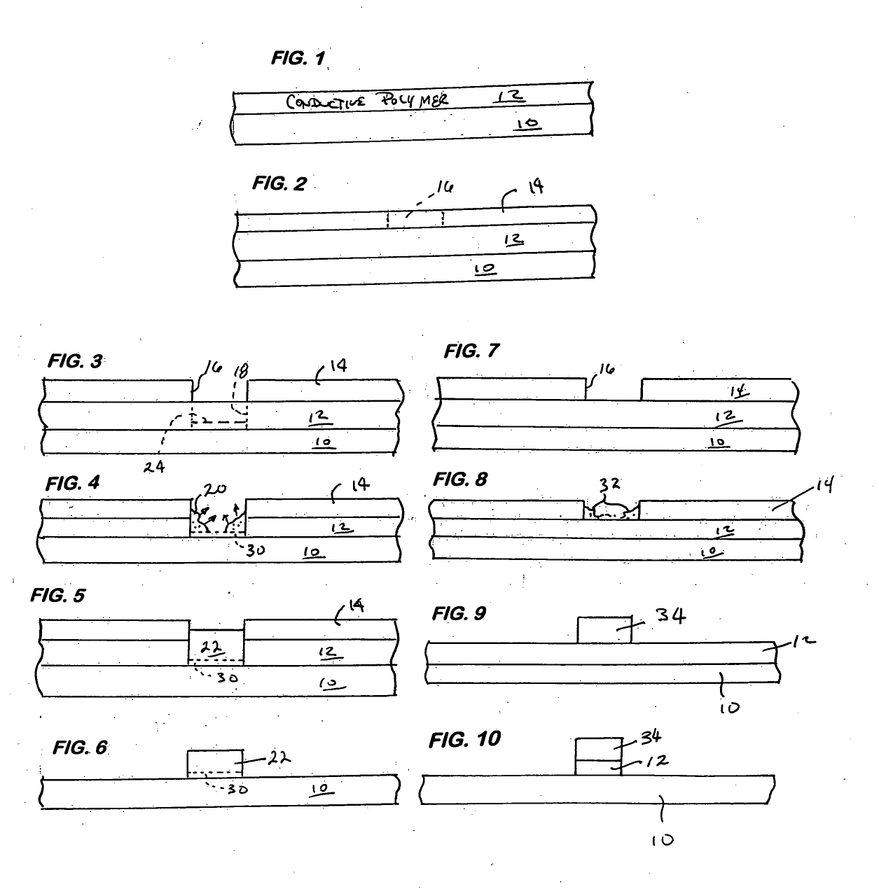

FIGS. 1 and 2 are exemplary first steps in what is shown in FIGS. 3-6 and FIGS. 7-10 as two alternatives processes that comprise the present invention. Both involve the use of a conductive polymer layer that is deposited on a substrate and then subsequently treated to produce ultra-small structures.

FIG. 1 is a diagrammatic cross sectional view of a non-conductive, semi-conductive or a hard substrate 10 that has been coated with a first layer 12 of a suitable conductive polymer, or other conductive material. Examples of non-conductive substrates include glass, oxidized silicon, plastics and many others, the semi-conductive substrates can include doped or undoped silicon, compound semiconductor materials (GaAs, InP, GaN, . . . ), and the hard materials can include metal plates or sheets (aluminum, copper, iron alloys . . . ), ceramic materials .

The conductive polymer layer 12 can be applied by conventional spin coating techniques, an evaporation process, or other suitable coating techniques that are familiar to those skilled in the art. Indeed, any process that can deposit a coating of the conductive polymer material can be used. Examples of suitable conductive materials include polypheneylene (PPV), methano [70] fullerene, (MDMO), Poly(3-methylthiophene) (pMeT), Poly(dithiono[3,4-b:3′,4′-d]thiophene) (pDTT1), Poly(3-p-fluorophenylthiophene) (pFPT), PEDT- Poly(ethylene-dioxythiophene), Plyaniline, Polythiophene, and Polypyrrole.

Thereafter, as shown in FIG. 2, a second layer 14 is deposited on the conductive layer 12. The second layer 14 is a masking, or protection, layer and can be comprised of a photoresist layer or a layer of resist material that can be patterned. Here again, any coating method can be used to apply the second mask layer that will work for the particular material chosen, for example, the photoresist could be deposited by spin coating techniques, while other masking layer materials could be coated by other known techniques. The function of the second layer 14 is to both protect the CP layer 12 during subsequent etching processing and may be a material that can be removed following the electroplating step if necessary for the intended application. This permits the structure, which is ultimately to be formed by electroplating, to remain on the non-conductive substrate.

FIG. 2 also shows in dotted line at 16 where the second layer 14 will be patterned using conventional exposure processing techniques or by a direct writing technique designed for the particular masking material being used or for the photoresist (PR) material where that is used. It should be understood that any method of patterning, known to those skilled in semiconductor processing that results in the desired feature size may be used to pattern the second layer 14.

FIG. 3 shows that next step where the portion 16 of the second layer has been removed, thus exposing a desired area or areas of the underlying CP layer 12 that can have a variety of outer shapes, spacing there between, and sizes. At this point in the processing several options become possible.

As shown in FIG. 3, RIE or other techniques known to those skilled in the art can be used to completely remove the selected areas of the CP layer 12 as shown in dotted line at 18. Alternatively, and depending on the effect desired for the CP layer removal, chemical etching techniques, familiar to those skilled in the art, could be used to remove the selected portions of the CP layer 12. In that regard, isotropic etching, associated with chemical etching processes, removes material in multiple directions, while RIE etching techniques removes material primarily in a single direction.

Where the full depth of the CP layer 12 has been removed, thereby exposing the underlying substrate layer 10, it is also possible, and within the scope of this invention, to provide an adhesion or barrier layer on the substrate 10 in the form of a thin film or layer 30, shown by a dotted line, prior to plating. This thin film or layer 30 can be deposited, for example, by e-beam evaporation or other similar techniques that will deposit the desired thin film or layer 30. That thin film or layer 30, an adhesion or barrier layer, can be, for example, a thin nickel layer. It should also be understood that the thin film or adhesion layer 30 should be thin enough so that the thin film or layer 30 does not short the side walls of the CP layer 12 to the top of the structure.

Alternatively, only a portion of the full depth of the CP layer 12 can be removed, as is shown by the dotted horizontal line 24 in FIG. 3. The exact depth of the etched opening in CP layer 12 can vary, and can influence the size of the ultra-small structures being formed.

FIG. 4 shows the initial depositing of the electroplating material into the hole formed in the first and second layers, 12 and 14, respectively, and onto the surface of the non-conductive substrate. As the arrows demonstrate, the desired metal being deposited by electroplating, as shown at 20, will develop from the bottom corners and grow both inwardly and upwardly. Examples of the metal being deposited by electroplating techniques can include silver (Ag) and nickel (Ni) or any metal that can be electroplated.

FIG. 5 shows the next step in the process where a desired feature or structure 22 has been formed to the desired size and shape. Where the adhesion layer 30 is used, it would lie beneath the structure 22 as shown. Thereafter, both the conductive polymer layer 12 and the patterned or second layer 14 will be removed. This can be accomplished by using the “lift-off” method, familiar to those skilled in the art, or by an etching process, including either chemical etching or RIE techniques. Once the desired portions of the first and second layers 12 and 14 have been removed, the desired feature or structure 22 will remain on the non-conductive substrate as shown in FIG. 6. Here again, where used, the adhesion layer 30 would be positioned beneath the structure 22 and on the surface of the underlying substrate 10.

An alternative process is shown in FIGS. 7-10. FIG. 7 shows the processing at the point where the second, photoresist, layer 14 has been etched as shown in FIG. 2 but now, unlike the process step in FIG. 3, no further etching of the CP layer 12 will be done so that only portion 16 of the photoresist layer 14 will be removed. Then, as shown in FIG. 8, the alternative base structure of FIG. 7 is placed in the plating bath and plating is carried out as previously explained for FIG. 4. As shown in FIG. 8, the plating material 32 will fill in the hole previously formed in the photoresist or second layer 14. Once the desired amount of material has been deposited, the photoresist or masking second layer 14 can be fully removed, for example, by lifting off or etching techniques, leaving the desired feature or stucture 34 remaining of the surface of CP layer 12 as shown in FIG. 9.

In addition, the CP layer can also be further etched and removed leaving the desired feature or structure 34 on a portion of the CP layer 12 lying directly under the structure 34 as shown in FIG. 10.

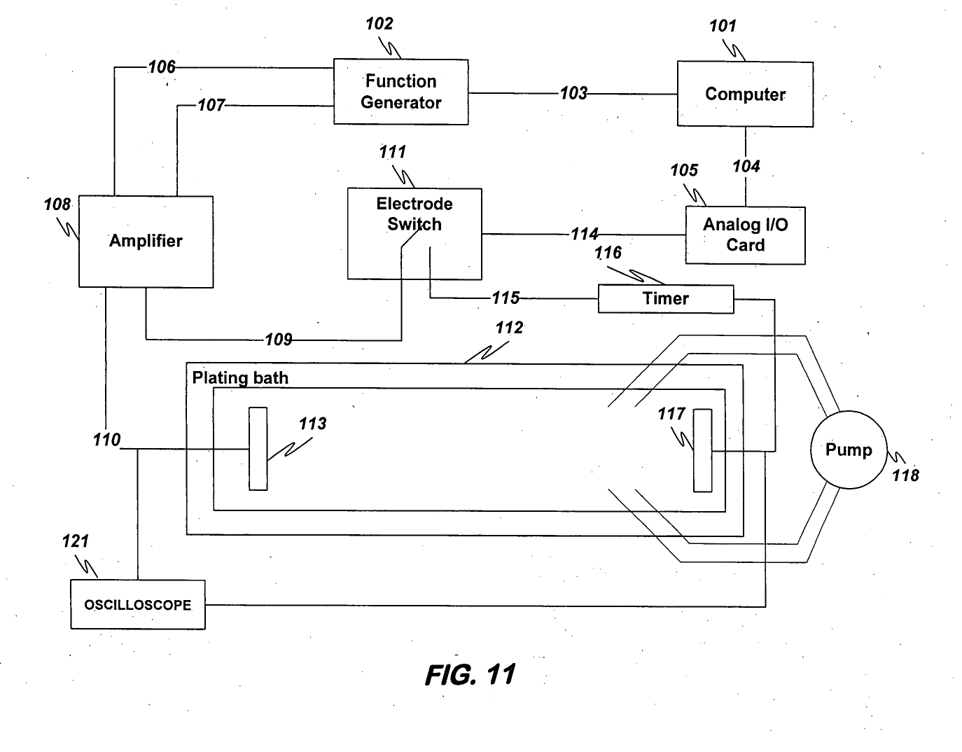

FIG. 11 is a schematic drawing of an exemplary configuration of an electroplating apparatus according to embodiments of the present invention. A computer, such as personal computer 101, is connected to a function generator 102, e.g., by a standard cable such as USB cable 103. Personal computer 101 is also connected to analog input-output card 105, e.g., by standard USB cable 104.

Waveform functions on the personal computer 101 are drawn using a standard program included with function generator 102. After the personal computer 101 downloads the waveforms to the function generator 102, the function generator sets characteristics such as amplitude, period, and offset of its electrical output signal. The output of function generator 102 is sent to the current amplifier 108 along cables 106 and 107. The cables 106 and 107 may be, e.g., standard USB cables.

In cases where the output current of the function generator is insufficient to carry out the plating, an amplifier 108 can be introduced between the function generation and the plating bath 112. Amplifier 108 increases the output current of the function generator 102, making it sufficient to carry out the plating without experiencing a voltage drop. Current amplifier 108 maintains an appropriate voltage in plating bath 112 as deposition occurs. Any DC voltage offset introduced by an imperfect amplifier can be corrected by programming an opposite DC offset from the function generator.

Time between pulses is controlled via a program that triggers the function generator output. This program is also used to start and stop the plating.

The output signal from the current amplifier 108 is provided to electrode switch 111 on cable 109. Analog input-output (I/O) card 105 sends a signal to electrode switch 111 via cable/line 114. Analog input-output card 105 is controlled by an output signal from the computer 101.

Electrode switch 111 generates an output signal that is sent to timer 116 (via cable 115). The signal output from timer 116 is connected to anode 117 in the plating bath 112. In currently preferred embodiments, the anode is a silver (Ag) metal plate or a nickel (Ni) metal plate, but there is no requirement that the anode consist of silver, nickel, or other materials, including (without limitation) copper (Cu), aluminum (Al), gold (Au) and platinum (Pt) may be used and are contemplated by the invention.

A second output signal is sent from current amplifier 108 via cable 110 (which may be, e.g., a USB cable) to sample 113 (which comprises the surface/non-conductive substrate to be coated/plated by the metal on the anode 117). Sample 113 is the cathode. In presently preferred embodiments, non-conductive substrates are rectangular and are about 1 cm by 2 cm. There is no requirement that the non-conductive substrate be any minimum or maximum size.

An agitation mechanism such as agitation pump 118 is attached to plating bath 112. Agitation of the liquid in the bath 112 speeds up the deposition rate. The pump 118 agitates the solution, thereby moving the solution around the plating bath 112. The plating bath 112 is preferably large enough to permit even flow of the solution over the non-conductive substrate.

The effect of agitation depends on the size and shape of the device being plated. In some cases, agitation reduces the plating time to thirty seconds on some of the smaller devices and down to ninety seconds on larger ones. Agitation also facilitates uniform thicknesses on all the devices across the non-conductive substrate leading to higher yields. There are other known ways of agitation, including using an air pump to aerate the solution with air or another gas. For some applications, agitation may not-be preferred at all.

An appropriate plating solution is placed into plating bath 112. In presently preferred embodiments, a silver plating solution is used. In the currently preferred embodiment the solution is Caswell's Silver Brush & Tank Plating Solution.

To ensure that the plating bath 112 is getting the desired period and amplitude, an oscilloscope 121 can be connected directly to the plating bath.

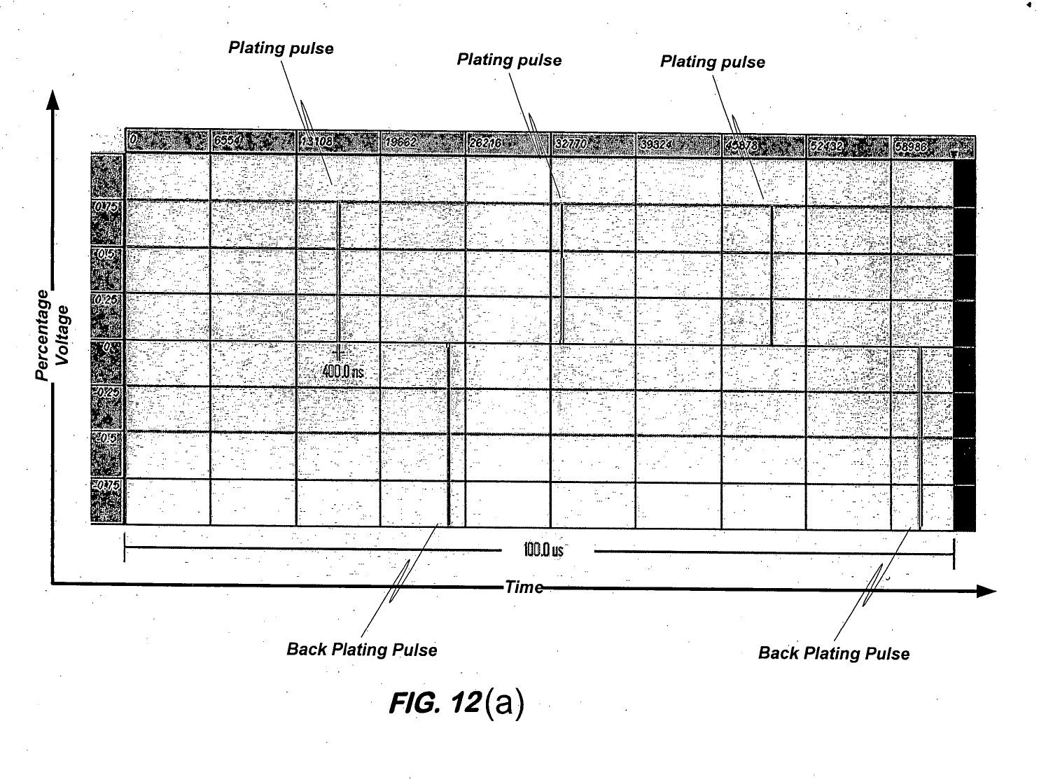

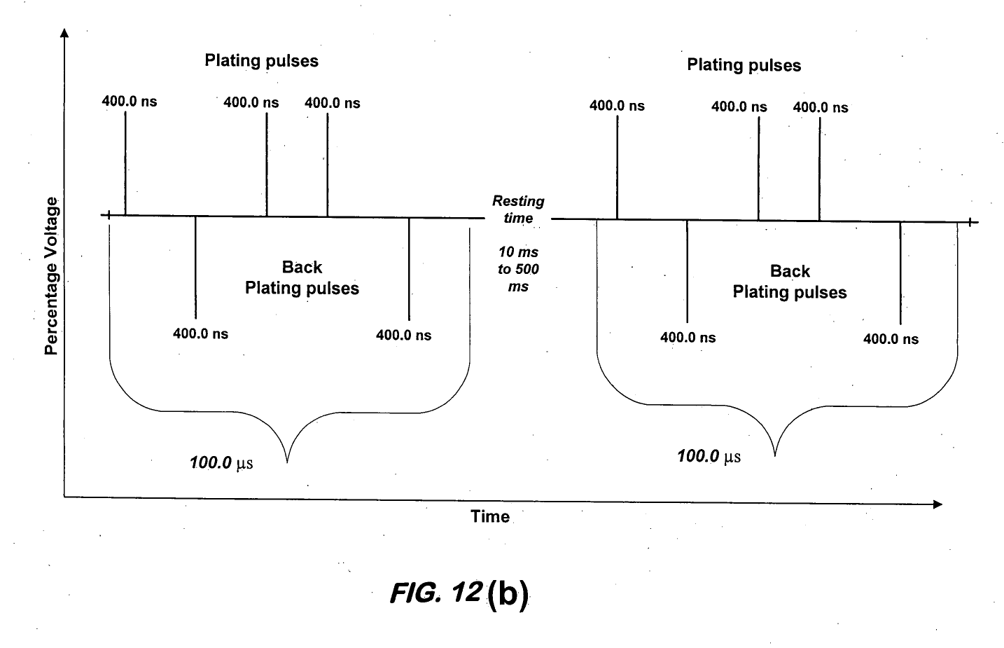

In the plating process, the voltage applied on the sample 113 is pulsed. FIGS. 12(a)-12(b) show a plot of a typical voltage waveform. In FIGS. 12(a)-12(b), the percentage of the total voltage applied on the sample is plotted versus time. In this waveform, a positive voltage pulse of between five and six volts is applied on the sample, and after some rest time, the voltage is reversed to a negative voltage. Plating occurs as the voltage applied on the substrate is negative-referenced to the counter electrode. It should be noted that FIGS. 12a and 12b show the voltage output from the waveform generator which is opposite in polarity to that applied to the sample. Hence, positive voltage in FIGS. 12a and 12b corresponds to a negative voltage on the sample thus plating material on the sample. It has been noticed that if the pulsed length is increased the plating pushes on the photoresist, creating slightly larger features.

During the intervals when the voltage is positive, material is removed from the structures. The optimum values of parameters such as peak voltage, pulse widths, and rest times will vary depending upon the size, shape and density of the devices on the substrate that are being plated, temperature and composition of the bath, and other specifications of the particular system to which this technique is applied.

In some embodiments, a series of plating pulses including at least one positive voltage pulse and at least one negative voltage pulse, are applied. Preferably each voltage pulse is for an ultra-short period. As used herein, an “ultra-short period” is a period of less than one microsecond, preferably less than 500 ns, and more preferably less than or equal to 400 ns. Preferably there is a rest period between each of the pulses in the pulse series. In presently preferred embodiments of the invention, the series of plating pulses is repeated at least once, after an inter-series rest time. Preferably the inter-series rest time is 1 microsecond or greater. In some embodiments of the present invention, the inter-series rest time is between 1 microsecond and 500 ms. As used herein, the term “ultra-short voltage pulse” refers to a voltage pulse that lasts for an ultra-short period—i.e., a voltage pulse (positive or negative) that lasts less than one microsecond, preferably less than 500 ns, and more preferably less than or equal to 400 ns.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A method of patterning ultra-small structures on a surface, comprising:
providing a substrate;
forming a first, conductive layer on the substrate;
forming a second layer on said first conductive layer;
defining and forming a desired pattern in said second layer;
removing selected portions of the conductive layer as defined by the patterned second layer thereby exposing portions of the substrate; and
growing ultra-small structures on the exposed portions of said substrate in an electroplating process.

2. The method of claim 1 wherein said ultra-small structures are comprised of a material selected from the group consisting silver (Ag), nickel (Ni), copper (Cu), aluminum (Al), gold (Au) and platinum (Pt).

3. The method of claim 1 wherein said electroplating process uses pulsed electroplating techniques and further comprises the step of applying a series of voltage pulses comprising at least one positive voltage pulse, wherein each said at least one voltage pulse is between 1.5 and 12 volts, and each said at least one voltage pulse lasts for less than 1 microsecond.

4. The method of claim 3 wherein each said at least one voltage pulse is for a period of less than 500 ns.

5. The method of claim 3 further comprising:
after said step of applying, resting for a rest period of at least 1 microsecond, and then repeating said applying step.

6. The method of claim 5 wherein the rest period is between 1 microsecond and 500 ms.

7. The method of claim 1 wherein said second layer is comprised of photoresist.

8. The method of claim 1 wherein said first conductive layer is comprised of polypheneylene (PPV).

9. The method of claim 1 wherein said first conductive layer is comprised of methano [70] fullerene, (MDMO).

10. The method of claim 1 wherein said first conductive layer is selected from the group consisting of polypheneylene (PPV), methano [70] fullerene, (MDMO), Poly(3-methylthiophene) (pMeT), Poly(dithiono[3,4-b:3′,4′-d]thiophene) (pDTT1), Poly(3-p-fluorophenylthiophene) (pFPT), PEDT-Poly(ethylene-dioxythiophene), Plyaniline, Polythiophene, and Polypyrrole.

11. The method of claim 1 including the further step of removing the first conductive layer and second layer material from around said ultra-small structures.

12. The method of claim 1 wherein said first conductive layer is a conductive polymer.

13. The method of claim 1 wherein said first conductive layer is a non-metallic conductor.

14. The method of claim 1 further including the step of removing the first conductive layer and the second layer from around said ultra-small structures and from said non-conductive substrate.

15. A method for patterning ultra-small features on a non-conductive surface comprising:
providing a non-conductive substrate;
forming a conductive layer on said non-conductive surface;
depositing a layer of photoresist on said conductive layer;
defining a pattern in said photoresist layer;
etching desired portions of said conductive layer as defined by the patterned photoresist layer to thereby expose a portion of the non-conductive substrate;
growing said ultra-small structures on the exposed portion of said non-conductive surface in an electroplating process; and
removing the remaining portions of said conductive layer and said photoresist layer.

16. The method of claim 15 wherein said conductive layer is selected from the group consisting of polypheneylene (PPV), methano [70] fullerene, (MDMO), Poly(3-methylthiophene) (pMeT), Poly(dithiono[3,4-b:3 ′,4′-d]thiophene) (pDTT1), Poly(3-p-fluorophenylthiophene) (pFPT), PEDT-Poly(ethylene-dioxythiophene), Plyaniline, Polythiophene, and Polypyrrole.

17. The method of claim 15 wherein said electroplating process is a pulse-electroplating process.

18. The method of claim 17 wherein said pulse-electroplating process includes a step of applying a series of voltage pulses comprising at least one positive voltage pulse, wherein each said at least one voltage pulse lasts for less than 1 microsecond.

19. The method of claim 18 wherein each said at least one voltage pulse period is less than 500 ns.

20. The method of claim 18 wherein said pulse-electroplating process includes:
after said step of applying, resting for a rest period of at least 1 microsecond, and then repeating said applying step.

21. The method of claim 18 wherein each said at least one voltage pulse is between 1.5 and 12 volts.

22. The method of claim 18 wherein the series of voltage pulses further comprises at least one negative voltage pulse.

23. A method for patterning ultra-small features on a semi-conductive surface comprising:
providing a semi-conductive surface having a conducting layer formed thereon;
depositing a mask layer on said conductive layer;
defining a pattern in said mask layer;
etching desired portions of said conductive layer as defined by the patterned mask layer to thereby expose portions of the semi-conductive layer there beneath;
growing said ultra-small structures on exposed said semi-conductive surface in a pulse-electroplating process; and
removing the remaining portions of the conductive layer and the mask layer from the semi-conductive substrate and the ultra-small structures.

24. The method of claim 23 wherein said ultra-small structures are comprised of a material selected from the group consisting of silver (Ag), nickel (Ni), copper (Cu), aluminum (Al), gold (Au) and platinum (Pt).

25. The method of claim 23 wherein said pulse-electroplating process comprises the step of applying a series of voltage pulses comprising at least one positive voltage pulse, wherein each said at least one voltage pulse is between 1.5 and 12 volts, and each said at least one voltage pulse lasts for less than 1 microsecond.

26. The method of claim 25 wherein each said at least one voltage pulse is for a period of less than 500 ns.

27. The method of claim 26 further comprising:
after said step of applying, resting for a rest period of at least 1 microsecond, and then repeating said applying step.

28. The method of claim 27 wherein said rest period is 1 microsecond to 500 ms.

29. The method of claim 23 wherein said mask layer is comprised of photoresist.

30. The method of claim 25, wherein the series of voltage pulses further comprises at least one negative voltage pulse.

31. The method of claim 1 wherein the step of removing selected portions of the first conductive layer includes leaving a portion of the first conductive layer so that the substrate is not exposed.

32. The method of claim 1 wherein the step of removing selected portions of the first conductive layer includes the step of completely removing the first conductive layer so that an upper surface of the substrate is exposed.

33. The method of claim 32 including the further step of depositing a thin adhesion layer on the exposed upper surface of the substrate.

34. The method of claim 33 wherein the adhesion layer comprises nickel.

35. The method of claim 1 wherein the substrate is non-conductive.

36. The method of claim 1 wherein the substrate is semi-conductive.

37. A method of patterning ultra-small structures on a surface, comprising:
providing a substrate;
forming a first, conductive layer on the substrate;
forming a second layer on said first conductive layer;
defining and forming a desired pattern in said second layer by removing portions thereof to expose surface portions of the first conductive layer; and
growing ultra-small structures on the exposed surface portions of the first conductive layer in an electroplating process.

38. The method of claim 37 including the additional step of removing additional portions of the first conductive layer on which there are no ultra-small structures.

39. The method of claim 37 wherein the substrate is comprised of a non-conductive material.

40. The method of claim 37 wherein the substrate is comprised of a semi-conductive material.
